(19) United States
(12) Patent Application Publication
(10) Pub. No.: US 2025/0169381 A1
(43) Pub. Date: May 22, 2025

(54) RECONFIGURABLE INTELLIGENT SURFACES USING LATCHING ROTATIONAL PATTERNS OF CHALCOGENIDE ELEMENTS

(71) Applicant: Dell Products L.P., Round Rock, TX (US)

(72) Inventors: Tejinder Singh, Kanata (CA); Navjot Kaur Khaira, Kanata (CA)

(21) Appl. No.: 18/512,304

(22) Filed: Nov. 17, 2023

(51) Int. Cl. H10N 70/20; H04B 7/04; H10N 70/00

(52) U.S. Cl. CPC H10N 70/231; H04B 7/04013; H10N 70/8828

(57) ABSTRACT

The technology described herein is directed towards phase-change material-based (e.g., chalcogenide) radio frequency components that can be used in unit cells of a reconfigurable intelligent surface. A tunable device for reconfigurable operation is described, in which the phase shift of each unit-cell of reconfigurable intelligent surface is varied by rotationally controlling the conductive state of the phase-change material. The rotational angle can be selectively controlled by heating elements that change portions of the unit cell's lower-resistance states relative to its higher resistance states, resulting in a phase change of a unit cell with respect to redirecting an electromagnetic wave. By arranging the heating elements below the material, and actuating each one as appropriate to change otherwise-latched resistive or conductive states within the overall unit cell surface, an analog-like device operation is achieved to provide more granular phase shift control of the cells of a reconfigurable intelligent surface.

### BACKGROUND

Reconfigurable Intelligent Surfaces (RIS), sometimes known as Intelligent Reflecting Surfaces (IRS) or metasurfaces, are artificially engineered structures capable of altering electromagnetic waves in ways not possible with natural materials. These surfaces can be modulated to induce specific changes in wave propagation, including reflection, refraction, absorption, and polarization.

Metamaterials are artificially engineered materials fabricated using a stack of metal and dielectric layers. These thin, two-dimensional metasurfaces can tune an electromagnetic wave's key properties, such as amplitude, phase, and polarization, as the electromagnetic wave is reflected or refracted by the surface. In other words, a reconfigurable intelligent surface is a two-dimensional surface whose surface can be electronically altered such that it changes the characteristics of any incoming electromagnetic wave, including the wave's phase.

Each metasurface typically is made up of (possibly up to) hundreds or thousands of unit cells, and because an individual unit cell can be controlled, reconfigurable intelligent surfaces can provide programmable and smart wireless environments. For example, one scenario is to use such a surface to intelligently reconfigure wireless communications; by adjusting the reflection and/or refraction of electromagnetic waves, reconfigurable intelligent surfaces can facilitate more optimal propagation conditions by enhancing signal clarity while minimizing interference. Such adaptability allows wireless signals to be directed to specific locations, amplifying reception in areas that traditionally experience weak or obstructed signals. For example, objects in the path of a wireless signal, such as buildings and trees, can block wireless communication signals at higher frequencies, including millimeter-wave frequency bands and even higher frequencies. While this can be overcome by installing a large number of base stations to provide coverage to otherwise blocked areas, doing so would increase the infrastructure costs many times. Instead, a relatively inexpensive metasurface can be installed at various locations to reflect and/or refract higher frequency signals to otherwise blocked or weak coverage areas.

### BRIEF DESCRIPTION OF THE DRAWINGS

The technology described herein is illustrated by way of example and not limited in the accompanying figures in which like reference numerals indicate similar elements and in which:

FIG. 1 is an exploded view representation of an example multilayer structure of a model of a unit cell for use in a reconfigurable intelligent surface, in which reconfigurability is achieved by using a chalcogenide material layer, in accordance with various aspects and implementations of the subject disclosure.

FIG. 2A is a planar implementation example of a chalcogenide-based element in which a phase change material (chalcogenide) can be actuated by a voltage or current pulse to change the resistance of the material, in accordance with various aspects and implementations of the subject disclosure.

FIG. 2B shows an example of reversible switching of phase change material between an amorphous (high resistance) and crystalline (low resistance) states using a first electrical pulse for one state change and a second electrical pulse for a state change reversal, in accordance with various aspects and implementations of the subject disclosure.

FIG. 3A is an example representation of a unit cell with a reconfigurable top layer in which a rotational angle (approximately forty-five degrees) is achieved by controllably heat-pulsing portions of the phase change material, in accordance with various aspects and implementations of the subject disclosure.

FIG. 3B is an example conceptual representation showing the example resistive and conductive states corresponding to FIG. 3A, in accordance with various aspects and implementations of the subject disclosure.

FIG. 4 is an example representation of the unit cell with a reconfigurable top layer in which a rotational angle (approximately thirty degrees) is achieved by controllably heat-pulsing pausing portions of the phase change material, in accordance with various aspects and implementations of the subject disclosure.

FIG. 5 is an example representation of the unit cell with a reconfigurable top layer in which a rotational angle (approximately fifteen degrees) is achieved by controllably heat-pulsing portions of the phase change material (at least those that are to be modified in their state relative to FIG. 4), in accordance with various aspects and implementations of the subject disclosure.

FIG. 6A is an example representation of a unit cell with a circular grid arrangement to achieve different rotational angles, in accordance with various aspects and implementations of the subject disclosure.

FIG. 6B is an example representation of a unit cell with a limited number of different rotational angles able to be selected, in accordance with various aspects and implementations of the subject disclosure.

FIG. 7 is an example representation of part of a reconfigurable intelligent surface with a lattice of unit cells, showing example unit cells having different rotational angles corresponding to different phase shifts to redirect an impinging wave, in accordance with various aspects and implementations of the subject disclosure.

FIG. 8 is an example representation of part of an example lattice of unit cells forming a reconfigurable intelligent surface, in which the unit cells can be controlled to vary their phase shifts to result in different reflective directions/states of an impinging wave, in accordance with various aspects and implementations of the subject disclosure.

FIG. 9 is an example graphical representation highlighting reconfigurability in phase shift of reflected wireless signals with a change in rotational angle via conductive and nonconductive portions of the phase change material, in accordance with various aspects and implementations of the subject disclosure.

FIG. 10 is an example graphical representation showing simulated magnitude response of a tunable unit cell (a reconfigurable intelligent surface element), in accordance with various aspects and implementations of the subject disclosure.

FIG. 11 is a flow diagram showing example operations related to changing phase shift of a unit cell of a reconfigurable intelligent surface by changing an operational rotational angle of the unit cell, in accordance with various aspects and implementations of the subject disclosure.

### DETAILED DESCRIPTION

Various aspects of the technology described herein are generally directed towards a phase change material-based device that can be used in a unit cell of a reconfigurable intelligent surface. In general and as will be understood, the phase change material can be configured to have different rotational angles based on conductive portions relative to nonconductive portions. The rotational angle determines the phase shift of a unit cell that includes or acts as the device.

As a result, control of the reconfigurable intelligent surface with respect to redirecting an impinging an electromagnetic wave is achieved by varying the rotational angle in relevant unit cells, and thereby controlling the phase shift of each affected unit cell. A controller or the like controls the conductive or resistive states over different areas of the phase change material to achieve desired wave redirection (reflection or refraction).

It should be understood that any of the examples herein are non-limiting. As one example, a unit cell of a reconfigurable intelligent surface is described that is based on switching elements made of chalcogenide materials, e.g., alloys based on germanium-antimony-tellurium (GeSbTe); however this is only one non-limiting example, and other materials, including those not yet developed, can be leveraged by the technology described herein. Thus, any of the embodiments, aspects, concepts, structures, functionalities or examples described herein are non-limiting, and the technology may be used in various ways that provide benefits and advantages in communications and computing in general. It also should be noted that terms used herein, such as “optimize” or “optimal” and the like only represent objectives to move towards a more optimal state, rather than necessarily obtaining ideal results.

Reference throughout this specification to “one embodiment,” “an embodiment,” “one implementation,” “an implementation,” etc. means that a particular feature, structure, or characteristic described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, or characteristics may be combined in any suitable manner in one or more embodiments/implementations. Repetitive description of like elements employed in respective embodiments may be omitted for sake of brevity.

The following detailed description is merely illustrative and is not intended to limit embodiments and/or application or uses of embodiments. Furthermore, there is no intention to be bound by any expressed or implied information presented in the preceding sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Further, it is to be understood that the present disclosure will be described in terms of a given illustrative architecture; however, other architectures, structures, substrate materials and process features, and steps can be varied within the scope of the present disclosure.

It will also be understood that when an element such as a layer, region or substrate is referred to as being “on” or “over” another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

Aspects of the subject disclosure will now be described more fully hereinafter with reference to the accompanying drawings in which example components, graphs and/or operations are shown. In the following description, for purposes of explanation, numerous specific details are set forth in order to provide a thorough understanding of the various embodiments. However, the subject disclosure may be embodied in many different forms and should not be construed as limited to the examples set forth herein.

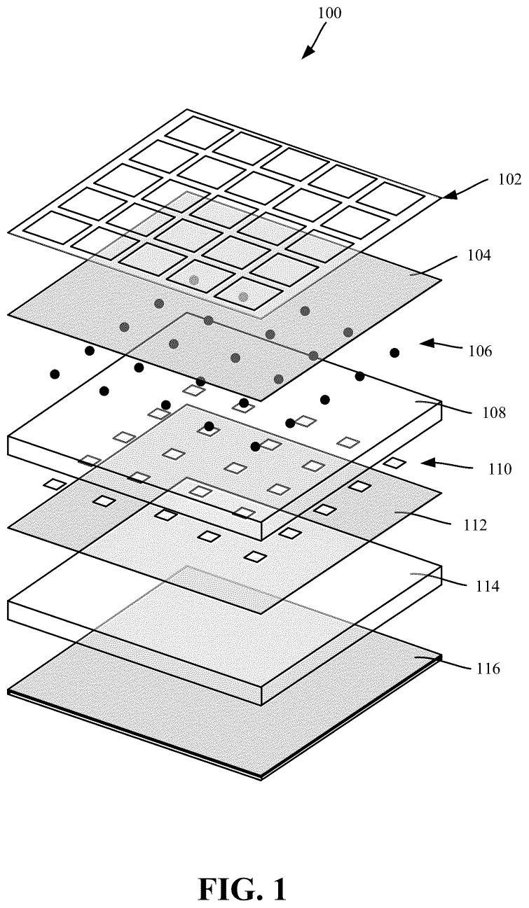

FIG. 1 shows an example multilayer structure 100 of a model of a unit cell, including a topmost layer 102 of a phase change material (e.g., Ge—Sb—Te, or GST alloy, made from reconfigurable chalcogenide). The layer 102 is shown as rectangles of phase change material that can be separately heated, however this is only a non-limiting example.

Moving downward in the representation of FIG. 1, the next lower (second) layer is a thermally conductive layer 104 under which a heater network 106 is embedded. The heater network 106 (e.g., refractory heater) in this example includes a grid of separate heating elements, represented in FIG. 1 as an array of dots, followed beneath by a layer of thermally insulator material 108. The thermally conductive layer 104 on the top of heater network 106 allows heat to conduct to the phase change material/GST alloy layer 102, while the thermally insulator material 108 below the heater network prevents the heat flow downwards.

A control/bias network 110 for the heaters is designed on a (fifth depicted) next lower layer, represented in FIG. 1 as an array of rectangles corresponding to the heating elements, followed by a dielectric layer 112, which is coated on a high permittivity substrate 114. The bottom of the substrate is coated by another thin metallization layer 116. The heating elements can be individually controlled as described herein, including to cause the phase change material to form rotational patterns/angles of conductive portions and nonconductive portions. Note that the sizes/thicknesses of the components and layers in any of the figures herein, including FIG. 1, are only for example purposes and not intended to convey any actual or relative sizes/thicknesses. Further, note that while the nonlimiting example layered design of FIG. 1 has numerous manufacturing advantages, there can be additional layers in other designs.

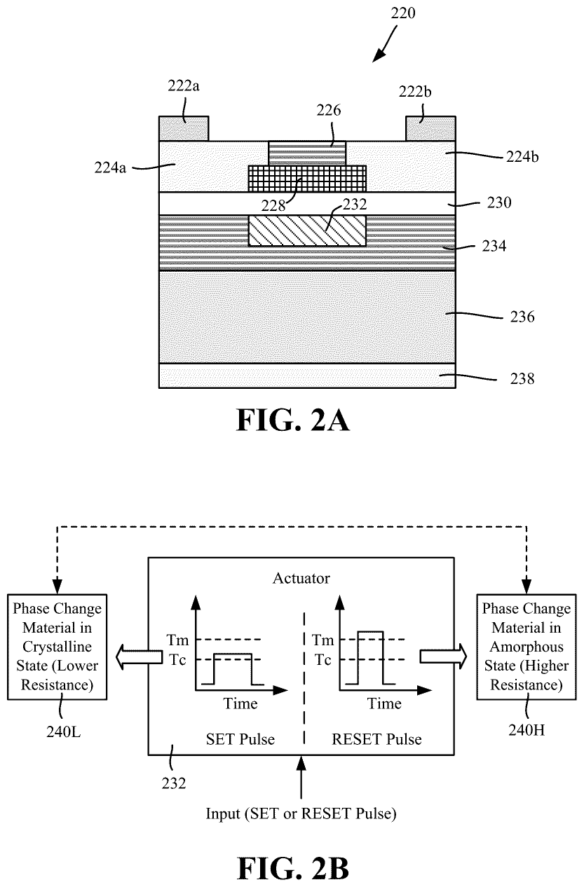

A planar implementation approach of the chalcogenide elements for the described technology is shown in FIG. 2A, e.g., part or all of a unit cell 220. In FIG. 2A, contacts 222a and 222b are depicted as being positioned above metallization components 224a and 224b, respectively. A thermal barrier 226 is shown above the chalcogenide material 228, which in turn is above a thin, thermally conductive insulation layer 230. An actuation mechanism 232 that outputs heat energy based on voltage or current pulses as described herein melt and quench the chalcogenide material 228 through the insulation layer 230, which when applied can change the state of the chalcogenide material 228.

Similar to FIG. 1, the actuation mechanism 232 is further contained by another thermal barrier 234, which is atop a dielectric substrate 236. A bottom metallization strip 238 is below the dielectric substrate 236.

Chalcogenide material is formed with alloys containing group VI elements such as sulfur(S), selenium (Se) and telluride (Te). Among these, the alloys formed from different ratio combinations of germanium, antimony, and telluride (Ge—Sb—Te, or GST alloys) are currently the most popular for radio frequency and optical memory applications. In general, single-phase alloys are made of germanium telluride (GeTe) and antimony telluride (Sb2Te3). Alloys include Ge1Sb2Te4, Ge2Sb2Te5, and Ge1Sb4Te7. Depending on the alloy used, the properties range from high stability and low speed to low stability and high speed. The GST alloys have a unique property of reversibly switching between amorphous and crystalline states upon specific heat treatment by means of electrical pulses, hence the name “phase-change.” The state in which atoms are arranged in a disorderly manner (short range order) is called the amorphous state, whereas the state where atoms are organized in an orderly manner (long range order) is called crystalline state. The disordered amorphous state has a lower mean free path of conduction for electrons that impedes current flow due to electron scattering, thus resulting in a higher resistance when compared to the crystalline state.

As shown in FIG. 2B, a medium amplitude (typically 1-2 V) and relatively longer duration (typically on the order of 100 nanoseconds) SET electrical pulse (e.g., represented in the left portion of the actuator 232) is used for crystallization during a transition to the ON (lower resistance) state (block 240L). Energy from the SET pulse heats the material for sufficient time to crystallize the material and provides adequate time for atoms to reorganize to an orderly arrangement, thus transforming from an amorphous state to crystalline state. To change to the amorphous (higher resistance) state (block 240H), a short duration (typically less than 100 nanoseconds) and high amplitude (typically >2 V) RESET electrical pulse is used. The RESET pulse provides sufficient energy to melt the material to disorder the atoms followed by rapid quenching to freeze the atoms, thus transforming the material from the crystalline state to the amorphous state. Significantly, only a short duration pulse is used to switch the state of the material between states; the pulse transforms the material and latches the material into the state, without the need for continuous power in either state. The pulse duration and amplitude can be further optimized by tuning the ratio of GeSbTe alloy ratios.

The operation principle of the example unit cell structure 100 of FIG. 1 is based on the many orders of magnitude resistance change that chalcogenide phase change GST alloys undergo when provided a specific heat treatment using a pulse, as described with reference to FIG. 2B. Such materials can reversibly transition between a low resistance (metallic/conductive) state to a high resistance (insulator/resistive) state. This transition occurs due to the change in crystal structure of the alloy, which changes from amorphous to crystalline. In order to control the states of the material, the heater network 106 has a matrix of heaters (heating elements) placed below the phase change material (chalcogenide material) layer 102. The heating elements can be individually actuated by an electronic pulse via the control/bias network 110. In the absence of any actuation, the material is in its amorphous (high resistance) state and acts as an insulator. A limited area (portion) of the chalcogenide material 102 is actuated by each heating element, and as more and more heaters are actuated, a desirably controlled area of the material transitions to the low resistance metal state. Hence, a dynamic change in the shape of the reflection surface, which can correspond to its capacitance (area of the topmost conductor) can be achieved at a high speed, which facilitates ultrafast reconfigurable operation.

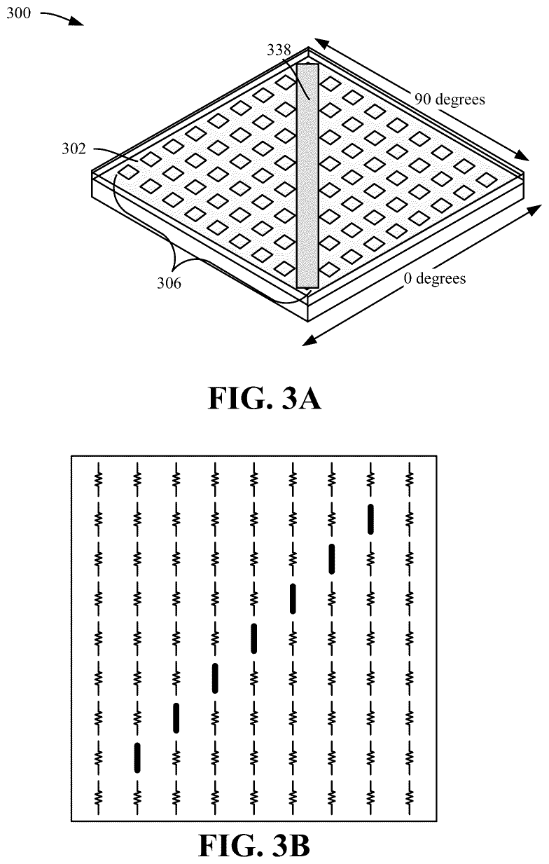

FIG. 3A shows a device 300 configured to have a relatively narrow width of conductive material 338 at a desired angle (approximately forty-five degrees) obtained by pulsing (as needed) the corresponding heating element(s) 306 (the rectangles below the chalcogenide material layer 302) to create the appropriate higher or lower resistance states in each portion. The shaded rectangle 338 generally represents the conductive area. FIG. 3B conceptually shows the example resistive and conductive states corresponding to FIG. 3A after actuation of the appropriate heater elements to obtain these states, where the resistor symbols represent nonconductive states and the solid lines represent the conductive states.

To summarize, the operation of the unit cell is based on the significant conductivity alteration exhibited by the chalcogenide phase change GST alloys, (a shift on the order of six orders of magnitude) when subjected to the above-described thermal pulsing. This configuration enables the material to change between low-resistance (metallic) and high-resistance (insulative) states, attributed to its metamorphic crystalline structure. The state regulation is mechanized by a matrix of heaters situated beneath the GST layer. These strategically dimensioned heaters are individually activated by electronic pulses. Their actuation catalyzes localized phase transitions in the GST, enabling fast, dynamic modulation of the reflective surface for adaptable operation.

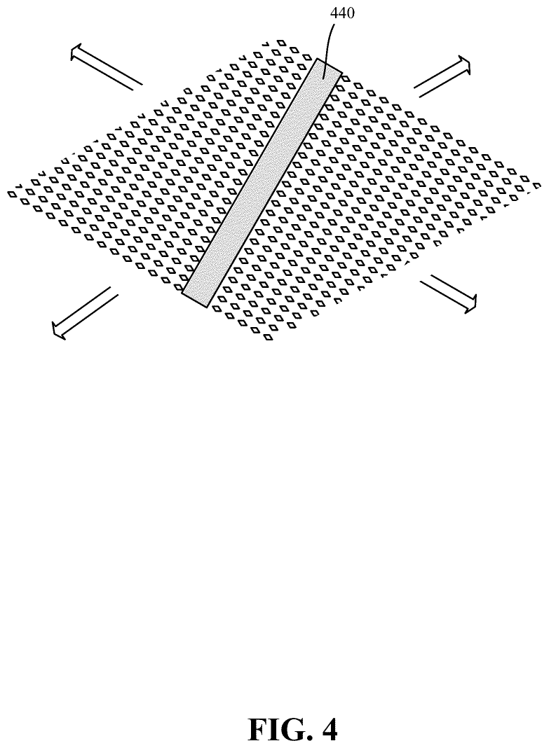

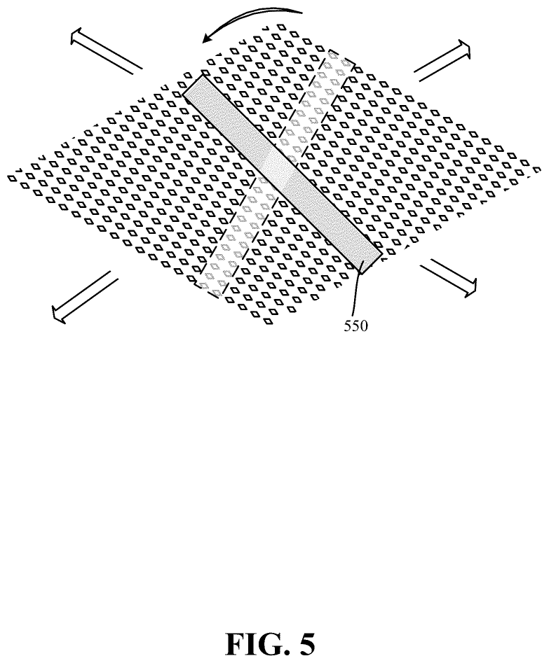

It should be noted that the heating elements of the heater network can be, but need not be, symmetrical or substantially symmetrical with respect to their separation distances. Further, the heating elements can be, but need not be, the same widths or lengths, or substantially the same widths or lengths, nor need they necessarily be parallel or substantially parallel to one another. Further note that the actual numbers of heating elements and their arrangements shown herein are only for example explanatory purposes rather than being representative of any actual device. For example, FIG. 1 depicts a 5×5 array of heating elements, while FIGS. 3A and 3B depict a 9×9 array of heating elements and FIGS. 4 and 5 show an even larger array of such elements. In some implementations, a single heating element can heat up more than one portion of chalcogenide material, or multiple heating elements can heat up a single portion of chalcogenide material. There can be more than one layer of heating elements.

FIG. 4 shows a different operational rotational angle (approximately thirty degrees) relative to FIG. 3A of the device obtained by controlling the heater network to modify the conductive and resistive portions of the chalcogenide material to create the appropriate higher or lower resistance states that form the operational rotational angle of lower resistance/conductive states (block 440). In this example, the lower resistance portions produce a contiguous group at the desired angle, while the two resistive portions are generally discontiguous subgroups of the resistive areas. Note that while a single contiguous group of conductive material portions 440 is shown, it is feasible to have any number of separate (e.g., not contiguous) conductive portions and/or resistive portions in a given state of a unit cell; various simulations and/or empirical evaluations can be used to determine the desired characteristics of a unit cell in one of its many configurable states. For example, two (or more) different and/or separated conductive angles, not necessarily the same width or length, can be achieved on a unit cell at the same time, with the resulting phase shift simulated and/or measured, such as to slightly increase or decrease the phase shift without needing a very fine grid of heating elements.

FIG. 5 shows a different operational rotational angle (approximately fifteen degrees) obtained by a group of contiguous conductive portions 550. In this example, the conductive portions 550 result in a different rotational angle relative to the rotational angle shown in FIG. 4 (block 440). Note that to conserve energy, only the portions of the material to have their states changed are pulsed by the heating elements. Thus, for example, the general area corresponding to portions that are conductive in FIG. 4 and which are also conductive in FIG. 5, generally proximate the centers of the low resistance portions, need not have their states changed because they are already conductive portions. This area that need not be changed is represented by the intersection of the dashed block (what was the already conductive state portions in FIG. 4) not needing to be modified into the conductive portions as represented by the solid, shaded block 550.

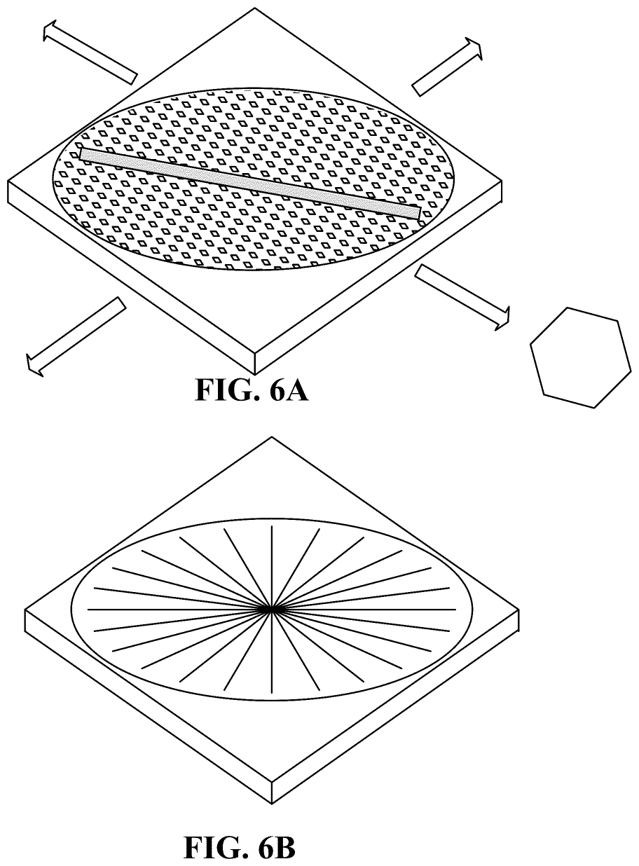

FIG. 6A depicts another concept, in which a unit cell has a generally circular arrangement of heating elements and corresponding portions of phase change material. Such a configuration can reduce the number of heating elements and phase change material in an implementation in which only angular patterns are involved. Note that instead of a square unit cell with a circular arrangement of heating elements and phase change material, such a cell can be hexagonal, for example, so that the unit cells can be tessellated to fit more closely together on a reconfigurable intelligent surface without large gaps or overlapping.

FIG. 6B shows a similar concept in which only a limited number of angles are involved for a given implementation. In this example, the available angles are fifteen degrees apart from one another. As can be appreciated, there can be heating elements and phase-change material located only where appropriate for the desired set of possible angles, and can be relatively lengthy portions corresponding to the depicted lines in FIG. 6B rather than individual rectangles or the like as in FIG. 6A.

A significant attribute of the GST alloys is their transient power dependency; they necessitate electrical pulses solely during phase alternations. Post-transition, the material remains stable in its acquired state, without needing any constant or refreshing power. This characteristic significantly reduces a reconfigurable intelligent surface panel's power expenditure over relatively prolonged operational intervals.

Thermal influence from individual heaters is localized, ensuring zero or near-zero thermal interference among neighboring heaters. This permits conducting patterns to be controlled on the GST layer, as illustrated in FIGS. 3A, 4, and 5. The reconfigurable intelligent surface design can efficiently modulate the conducting patches' dimensions through planar rotational shift, achieved in nanoseconds. The transition kinetics and activation pulse duration intricacies are influenced by the precise GST alloy composition.

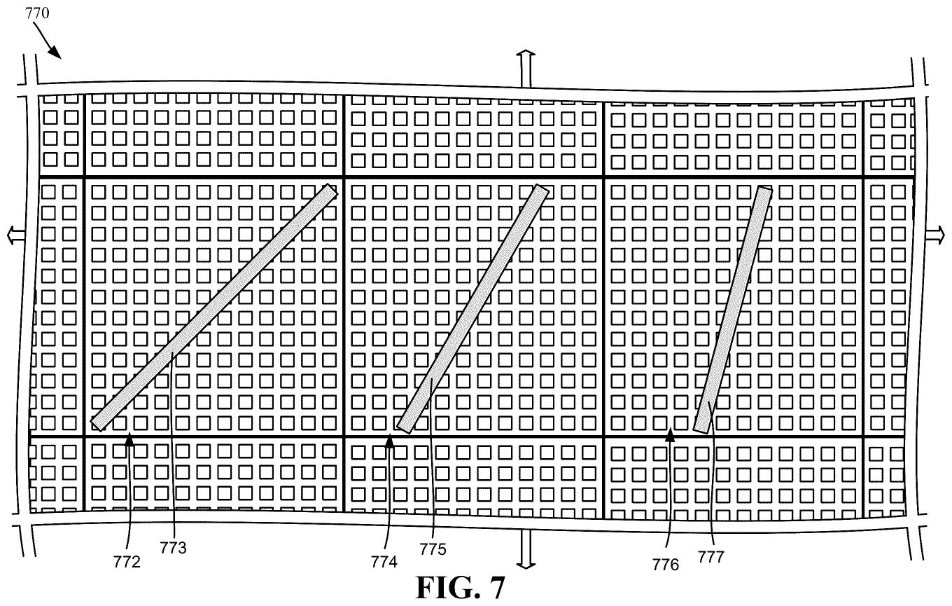

FIG. 7 shows part of a reconfigurable intelligent surface 770 in which at least three unit cells are controlled to have different operational rotational angles corresponding to different phase shifts. In the example of FIG. 7, three unit cells 772, 774 and 776 are depicted as having conductive portions 773, 775 and 777, respectively, with different operational rotational angles of approximately forty-five degrees, approximately thirty degrees and approximately fifteen degrees, respectively. As is understood, because of the different corresponding phase shifts, an impinging electromagnetic wave will be redirected differently from each of the unit cells 772, 774 and 776, such as to result in constructive (or destructive) interference relative to a target location.

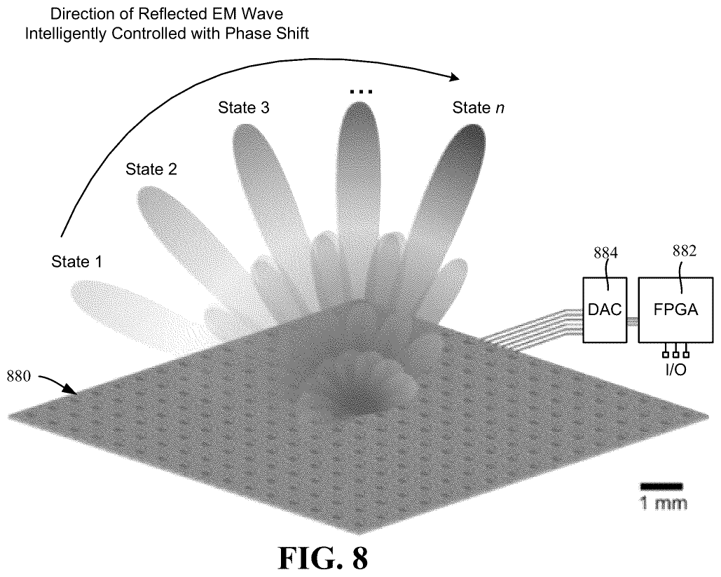

As shown in the example surface 880 of FIG. 8, a reconfigurable intelligent surface can be formed by arranging multiple unit cells in a two-dimensional m×n array. In general, a reconfigurable intelligent surface is a planar surface built from an array of passive reflecting (or refracting) elements, each of which can independently impose the appropriate phase shift on the incoming signal. By adjusting the phase shifts of the reflecting elements, reflected signals can be reconfigured to propagate towards their desired directions. As described herein, the reflection coefficients of each element can be reconfigured in real-time to adapt to the dynamically fluctuating wireless propagation environment. By appropriately tuning the phase shifts of the reflecting elements of the reconfigurable intelligent surface, the reflected signals can be constructively superimposed with those from the direct paths for enhancing the desired signal power (constructive interference), or destructively combined for mitigating deleterious effects of multiuser interference (destructive interference). Hence, reconfigurable intelligent surfaces provide additional degrees of freedom to further improve the system performance.

In the outdoors, a reconfigurable intelligent surface can be applied to buildings, windows and so forth to enhance the signal in dead or weak zones and strengthen the signal in already covered areas. A reconfigurable intelligent surface can also be deployed for spatial microwave modulation in a typical office room and can passively increase the received signal power by an order of magnitude, or completely null it. Furthermore, a reconfigurable intelligent surface naturally operates in full-duplex (FD) mode without self-interference or introducing thermal noise. Therefore, reconfigurable intelligent surfaces achieve higher spectral efficiency than active half-duplex (HD) relays, despite their lower signal processing complexity relative to that of active full duplex relays requiring sophisticated self-interference cancellation.

Thus, as shown in FIG. 8, a reconfigurable intelligent surface 880 formed from an array of unit cells is able to vary the direction of a reflected beam/electromagnetic wave based on intelligently controlling the phase shifts of the unit cells, in this example via a field-programmable gate array. With respect to configuring the array digitally, in this example a field-programmable gate array (e.g., FPGA/controller) 882 is used to provide the output, mapped to the heating elements of the cells and converted (DAC 884) to the appropriate RESET or SET pulses based on the zero- or one-bit pattern instruction, to each heating element of each cell of the array of cells as implicated to change state. The output gives instructions to the individual heating/switching elements of the individual unit cells, independent from each other switching element, and thereby sets the cell's phase shift independent from each other cell. In other words, actively tuning the phase change material—in each cell can be individually controlled by the field-programmable gate array 882, which provides a coding output of 0 s and 1 s.

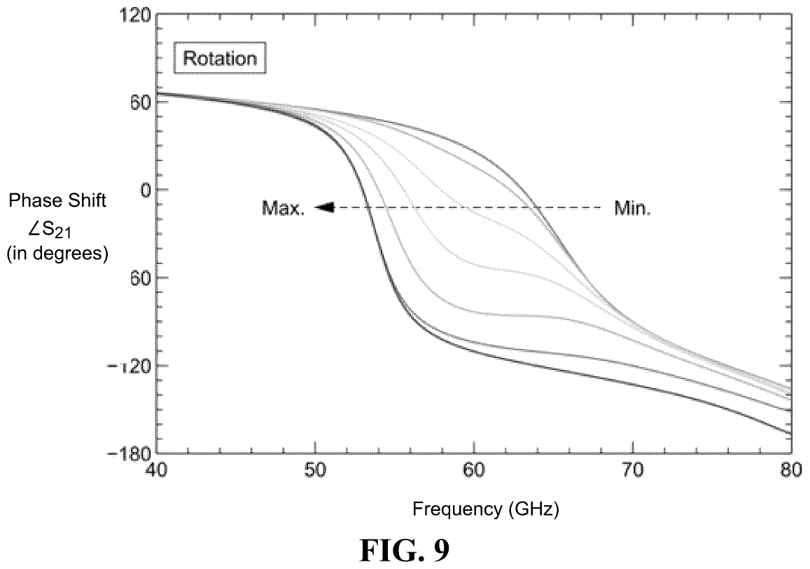

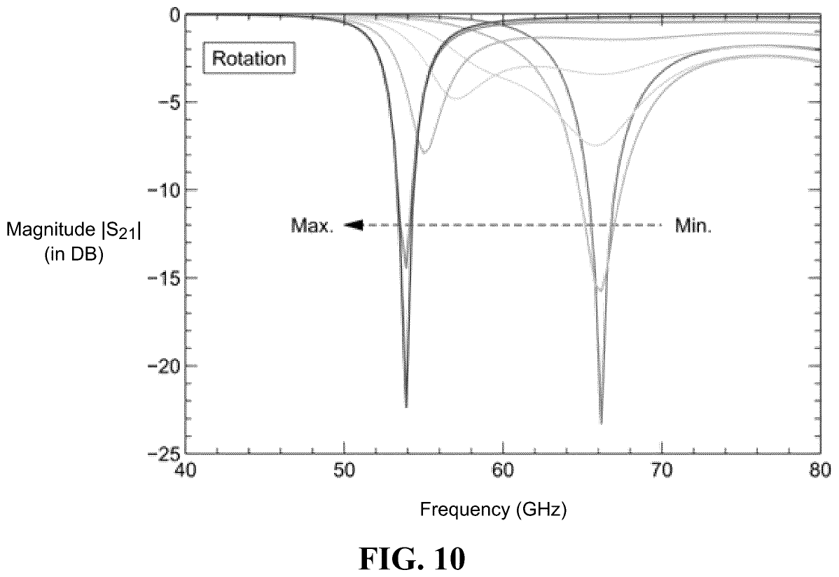

Advanced electromagnetic simulation platforms have been used to validate the radio frequency reflective attributes of the unit cell with different rotational angles, correlating the conductive GST alloy expansiveness. In the simulation(s), a unit increment of seven different rotational angles facilitates the requisite phase shift modulation for electromagnetic signals reflected by the unit cell. This modulation results in a notable 16 GHZ bandwidth in the 60 GHz mmWave-Band, as shown in FIGS. 9 and 10. More particularly, FIG. 9 represents the simulation response using a full-field 3D finite element method modeling, which shows the significant reconfigurability in phase shift of a reflected wireless signal with a change in rotational angle of the GST patch demonstrating significant phase shift changes around 60 GHZ. FIG. 10 shows the simulated magnitude response corresponding to FIG. 9.

The technology described herein can function with a minimal power supply, as the electrical pulse is applied only during a change of configuration, a significant advantage over technologies that need continuous power to hold one of the states. Another significant and beneficial feature of this design is that the unit cells described herein can receive and transmit electromagnetic waves simultaneously, hence achieving full-duplex operation.

The technology described herein is suitable for reconfigurable intelligent surface-assisted wireless communications. Because the direct path between the access point and a target of interest can be fully/partially obstructed by other objects, the use of a reconfigurable intelligent surface can substantially improve the wireless network performance, particularly in crowded indoor/outdoor scenarios.

For example, with respect to an outdoor scenario, by installing the reconfigurable intelligent surface on common surfaces such as building walls, windows, billboards, traffic signs and the like, and because as described herein the direction of the reflected and/or refracted beams can be controlled, including remotely controlled, reasonably optimal reconfigurable intelligent surface deployment positions can be identified, along with the corresponding size of the reconfigurable intelligent surface that is installed. Reconfigurable intelligent surface placement and size can be in conjunction with the planning for a base station's position, or done afterwards by identifying the blind areas of poor signal strength in the network coverage map. This can not only improve the signal reception in the shadow areas, but also improve the data rates in the areas with an already good signal reception. Thus, a reconfigurable intelligent surface can be used for solving the network coverage problem of 5G/6G and even beyond, without adding much power/cost overhead.

Consider by way of example a typical scenario of an outdoor urban area with a single base station. For low frequency radio transmissions, the signal can propagate to long and far distances without significant attenuation due to its long wavelength. However high frequency signals suffer serious attenuation and blockage from objects, whereby the wireless coverage from a single base station will be weak, or even provide no coverage in certain zones. Depending on the location of the base station and the positions of the users, the (mostly) optimal location and size for reconfigurable intelligent surface on billboards, highway signs, walls, windows, and corners of the buildings can be selected.

The signals from the base station reflect off of (or can be refracted by) the passive reconfigurable intelligent surface, can be steered in the direction of most users, and also can be steered to other reconfigurable intelligent surface in the area for further reflection/refraction. The users close to the base station generally receive a direct path signal from the base station, and (likely) also receive a reflected signal from a reconfigurable intelligent surface. The users further away from the base station (or behind obstructions) can receive the reflected or refracted signals from one or multiple reconfigurable intelligent surfaces. One or more of the reconfigurable intelligent surfaces also can employ amplification to boost signals if and when appropriate.

In an indoor scenario, windows and walls can be covered with reconfigurable intelligent surface films, which can be generally transparent, in order to extend wireless coverage indoors. By locating such films on the windows, the signals coming from the outside can be refracted and boosted inside the building, enhancing the coverage inside. The signals to an illegitimate user, e.g., an eavesdropper, can be blocked by destructive interference.

One or more implementations can be embodied in a device, including a phase change material, and an energy transfer component/controllable heater network that selectively transfers heat to different individual portions of the phase change material to change an operational rotational angle of the phase change material with respect to redirecting an electromagnetic wave impinging on the device, via a phase shift that is based on the operational rotational angle. The controllable heater network is controllable to output heat via pulsed energy to selectively change a first group of one or more of the different individual portions of the phase change material to a lower resistance state, and selectively change a second group of the one or more of the different individual portions of the phase change material to a higher resistance state higher than the lower resistance state; the first group is different from the second group.

The first group can include adjacent portions of the phase change material.

The device can be a unit cell of a reconfigurable intelligent surface. The controllable heater network can be insulated from the different individual portions of the phase change material by a thermally conductive layer of the unit cell.

The pulsed energy can latch the first group to the lower resistance state until subsequent pulsed energy changes at least part of the first group to the higher resistance state.

The controllable heater network can include a grid of heating elements, and respective heating elements of the grid can correspond to respective individual portions of the phase change material.

The controllable heater network can include a grid of respective heating elements, the respective heating elements can be associated with respective individual portions of the phase change material, and the device can be coupled to a controller that individually controls the respective heating elements via the pulsed energy to select whether the respective portions associated with the respective heating elements exist in the lower resistance state or the higher resistance state, respectively.

The phase change material can include at least one of an alloy: germanium telluride, germanium antimony telluride, or antimony telluride. There can be varying ratios of each alloy.

The unit cell can include a thermal insulator layer and a dielectric layer, the thermal insulator layer can be positioned between the heater network and a dielectric layer of the unit cell, and the phase change material in the lower resistance state and the dielectric layer can form a capacitor having a capacitance value determined by the operational rotational angle of the first group of phase change material in the lower resistance state.

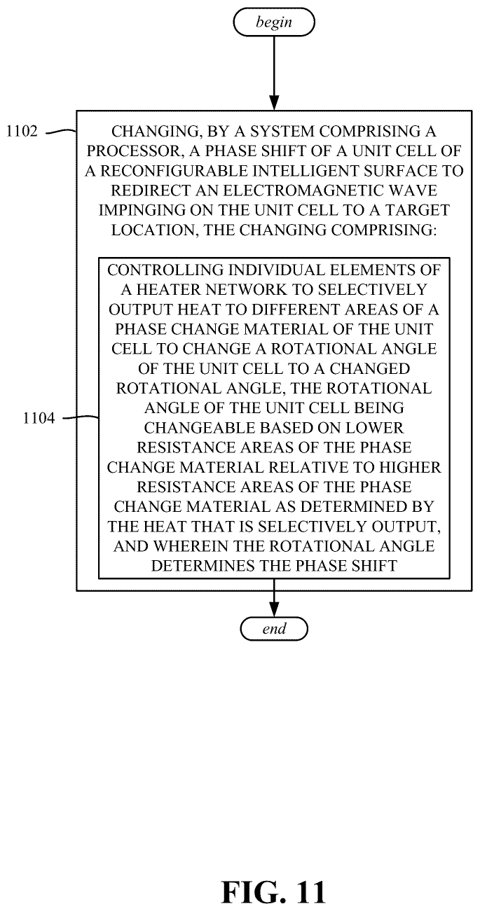

One or more example aspects, such as corresponding to example operations of a method, are represented in FIG. 11. Example operation 1102 represents changing, by a system comprising a processor, a phase shift of a unit cell of a reconfigurable intelligent surface to redirect an electromagnetic wave impinging on the unit cell to a target location. The changing comprises example operation 1104, which represents controlling individual elements of a heater network to selectively output heat to different areas of a phase change material of the unit cell to change a rotational angle of the unit cell to a changed rotational angle, the rotational angle of the unit cell being changeable based on lower resistance areas of the phase change material relative to higher resistance areas of the phase change material as determined by the heat that is selectively output, and wherein the rotational angle determines the phase shift.

The phase shift can be a first phase shift, the target location can be a first target location, the changed rotational angle can be a first rotational angle, and further operations can include obtaining, by the system, information representative of a second target location, and, in response to the obtaining of the information, redirecting, by the system, the electromagnetic wave to the second location, which can include controlling at least some of the individual elements of the heater network to modify the lower resistance areas of the phase change material relative to the higher resistance areas of the phase change material to change the first rotational angle to a second rotational angle that is different from the first rotational angle, the second rotational angle corresponding to a second phase shift of the unit cell.

Controlling the individual elements of the heater network to selectively output the heat can include pulsing a selected heating element with a voltage or current pulse to set a portion of the higher resistance areas to a lower resistance portion, the lower resistance portion corresponding to a location of the selected heating element.

The unit cell can be part of a reconfigurable intelligent surface that can include the unit cell and other unit cells arranged in a matrix that forms the reconfigurable intelligent surface; the changing the phase shift of the unit cell can redirect the electromagnetic wave to create constructive interference with the electromagnetic wave as redirected from at least one of the other unit cells, with respect to the electromagnetic wave as received at the target location.

The unit cell can be part of a reconfigurable intelligent surface that can include the unit cell and other unit cells arranged in a matrix that forms the reconfigurable intelligent surface; the changing the phase shift of the unit cell can redirect the electromagnetic wave to create destructive interference with the electromagnetic wave as redirected from at least one of the other unit cells, with respect to the electromagnetic wave as received at the target location.

One or more implementations can be embodied in a unit cell, including a phase change material distributed over an area that corresponds to a surface of the unit cell, and a heater network comprising individually controllable heating elements distributed over the area to transfer heat to different portions of the phase change material. The individually controllable heating elements can be controlled to output respective heat corresponding to energy pulses to the different portions to change an operational rotational angle of the phase change material to a changed rotational angle; the operational rotational angle is changeable based on higher resistance portions corresponding to a higher resistance state of the phase change material, and lower resistance portions corresponding to a lower resistance state of the phase change material. The operational rotational angle determines a phase shift of the unit cell that redirects an electromagnetic wave impinging on the unit cell to a target location.

The unit cell can be a first unit cell of a reconfigurable intelligent surface that can include the first unit cell and a second unit cell, and the individually controllable heating elements of the first unit cell can be controlled to change the operational rotational angle of the phase change material to the changed rotational angle to create constructive interference of the electromagnetic wave as redirected from the first unit cell with the electromagnetic wave as redirected from the second unit cell.

The unit cell can be a first unit cell of a reconfigurable intelligent surface that can include the first unit cell and a second unit cell, and the individually controllable heating elements of the first unit cell can be controlled to change the operational rotational angle of the phase change material to the changed rotational angle to create destructive interference of the electromagnetic wave as redirected from the first unit cell with the electromagnetic wave as redirected from the second unit cell.

The unit cell can include a thermally conductive layer between the phase change material and the heater network.

The unit cell can include a thermal insulator layer and a dielectric layer, and the thermal insulator layer can be positioned between the heater network and a dielectric layer of the unit cell. The phase change material in the lower resistance state and the dielectric layer can form a capacitor having a capacitance value determined by the operational width of the phase change material in the lower resistance state.

As can be seen, there is described herein tunable devices with respect to their phase shifts, including for unit cells, and a highly reconfigurable intelligent surface design, in which programming the actuation voltage to the chalcogenide elements realizes different effective operational angles, which leads to changes in the phases of a reflected electromagnetic wave. Analog-like fine tuning can be achieved by controlling the actuation states per heating element, whereby the phase precision comes without increasing the complexity of the design. The reconfigurable intelligent surface described herein can operate at high frequencies such as U-Band and at least some V-Band frequencies. Chalcogenide-based radio frequency switches and tuning elements demonstrate suitable performance at such frequencies.

Moreover, the compact size of the chalcogenide element makes it highly suitable for monolithic integration with a wide range of technologies. Each chalcogenide switch can be implemented with a compact footprint in sub-micron sizes, including for shrinking reconfigurable intelligent surface cell size at higher frequencies, in which chalcogenide capacitive elements/switches fit more than adequately and can be monolithically integrated within each unit cell.

Still further, the reconfigurable intelligent surface offers low ON-state insertion loss; because some of the chalcogenide materials including germanium telluride has very low crystalline state (ON state) resistance of less than one Ohm, and low OFF-state capacitance of 7 fF (femto-farad), the figure of merit of the switches is 0.04 ps (picoseconds), which is far higher than any known commercially available PIN diodes or semiconductor RF switches.

The reconfigurable intelligent surface design and tunable capacitive element technology described herein uses power only during a state transition, thus saving significant power when in a steady state. Indeed, the chalcogenide material (especially germanium telluride) only receives an electrical pulse when transitioning from one state to another, as the material subsequently latches into a state. Hence, chalcogenide material does not need a continuous supply of power, which makes the design described herein suitable for implementing reconfigurable intelligent surfaces that can benefit from low power for operation.

In general, the only electrically active element is the resistive heating matrix, unlike other solutions that necessitate intricate soldering and biasing. An FPGA micro-controller or the like regulates the reconfigurable intelligent surface, actuating precise GST alloy regions, e.g., through algorithmically determined patterns. The ability to maintain their state without continuous power along with the nanosecond phase transition aligns seamlessly with the sub-millisecond reconfiguration benchmarks of 6G, ensuring real-time adaptability for B5G/6G scenarios and beyond. The network of heaters sandwiched between the high thermal conductor for efficient heat transfer and refractory metal mesh further lowers the power consumption of the reconfigurable intelligent surface.

The rotational shifting via the GST alloy portions in a unit cell configuration facilitates significant shifts in conductivity when subjected to targeted thermal pulses. The multi-stack design (FIGS. 1 and 2A) is developed to be integrated monolithically. This offers a dynamic modulation of the reflective surface, with negligible power consumption. The dynamic metasurface is relatively straightforward to construct with a configuration of multiple unit cells, facilitating dynamic and rapid modulation of the smart surface.

What has been described above includes mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
a phase change material; and
a controllable heater network that selectively transfers heat to different individual portions of the phase change material to change an operational rotational angle of the phase change material with respect to redirecting an electromagnetic wave impinging on the device, via a phase shift that is based on the operational rotational angle, the controllable heater network being controllable to output heat via pulsed energy to selectively change a first group of one or more of the different individual portions of the phase change material to a lower resistance state, and selectively change a second group of the one or more of the different individual portions of the phase change material to a higher resistance state higher than the lower resistance state, wherein the first group is different from the second group.

2. The device of claim 1, wherein the first group comprises adjacent portions of the phase change material.

3. The device of claim 1, wherein the device comprises a unit cell of a reconfigurable intelligent surface.

4. The device of claim 3, wherein the controllable heater network is insulated from the different individual portions of the phase change material by a thermally conductive layer of the unit cell.

5. The device of claim 1, wherein the pulsed energy latches the first group to the lower resistance state until subsequent pulsed energy changes at least part of the first group to the higher resistance state.

6. The device of claim 1, wherein the controllable heater network comprises a grid of heating elements, and wherein respective heating elements of the grid correspond to respective individual portions of the phase change material.

7. The device of claim 6, wherein the controllable heater network comprises a grid of respective heating elements, wherein the respective heating elements are associated with respective individual portions of the phase change material, and wherein the device is coupled to a controller that individually controls the respective heating elements via the pulsed energy to select whether the respective portions associated with the respective heating elements exist in the lower resistance state or the higher resistance state, respectively.

8. The device of claim 1, wherein the phase change material comprises at least one of an alloy: germanium telluride, germanium antimony telluride, or antimony telluride.

9. The device of claim 1, wherein the unit cell comprises a thermal insulator layer and a dielectric layer, wherein the thermal insulator layer is positioned between the heater network and a dielectric layer of the unit cell, and wherein the phase change material in the lower resistance state and the dielectric layer form a capacitor having a capacitance value determined by the operational rotational angle of the first group of phase change material in the lower resistance state.

10. A method, comprising,
changing, by a system comprising a processor, a phase shift of a unit cell of a reconfigurable intelligent surface to redirect an electromagnetic wave impinging on the unit cell to a target location, the changing comprising:
controlling individual elements of a heater network to selectively output heat to different areas of a phase change material of the unit cell to change a rotational angle of the unit cell to a changed rotational angle, the rotational angle of the unit cell being changeable based on lower resistance areas of the phase change material relative to higher resistance areas of the phase change material as determined by the heat that is selectively output, and wherein the rotational angle determines the phase shift.

11. The method of claim 10, wherein the phase shift is a first phase shift, wherein the target location is a first target location, wherein the changed rotational angle is a first rotational angle, and further comprising obtaining, by the system, information representative of a second target location, and, in response to the obtaining of the information, redirecting, by the system, the electromagnetic wave to the second location, comprising controlling at least some of the individual elements of the heater network to modify the lower resistance areas of the phase change material relative to the higher resistance areas of the phase change material to change the first rotational angle to a second rotational angle that is different from the first rotational angle, the second rotational angle corresponding to a second phase shift of the unit cell.

12. The method of claim 10, wherein the controlling of the individual elements of the heater network to selectively output the heat comprises pulsing a selected heating element with a voltage or current pulse to set a portion of the higher resistance areas to a lower resistance portion, the lower resistance portion corresponding to a location of the selected heating element.

13. The method of claim 10, wherein the unit cell is part of a reconfigurable intelligent surface comprising the unit cell and other unit cells arranged in a matrix that forms the reconfigurable intelligent surface, and wherein the changing of the phase shift of the unit cell redirects the electromagnetic wave to create constructive interference with the electromagnetic wave as redirected from at least one of the other unit cells, with respect to the electromagnetic wave as received at the target location.

14. The method of claim 10, wherein the unit cell is part of a reconfigurable intelligent surface comprising the unit cell and other unit cells arranged in a matrix that forms the reconfigurable intelligent surface, and wherein the changing of the phase shift of the unit cell redirects the electromagnetic wave to create destructive interference with the electromagnetic wave as redirected from at least one of the other unit cells, with respect to the electromagnetic wave as received at the target location.

15. A unit cell, comprising:
a phase change material distributed over an area that corresponds to a surface of the unit cell; and
a heater network comprising individually controllable heating elements distributed over the area to transfer heat to different portions of the phase change material, wherein the individually controllable heating elements are controlled to output respective heat corresponding to energy pulses to the different portions to change an operational rotational angle of the phase change material to a changed rotational angle, wherein the operational rotational angle is changeable based on higher resistance portions corresponding to a higher resistance state of the phase change material, and lower resistance portions corresponding to a lower resistance state of the phase change material, and wherein the operational rotational angle determines a phase shift of the unit cell that redirects an electromagnetic wave impinging on the unit cell to a target location.

16. The unit cell of claim 15, wherein the unit cell is a first unit cell of a reconfigurable intelligent surface comprising the first unit cell and a second unit cell, and wherein the individually controllable heating elements of the first unit cell are controlled to change the operational rotational angle of the phase change material to the changed rotational angle to create constructive interference of the electromagnetic wave as redirected from the first unit cell with the electromagnetic wave as redirected from the second unit cell.

17. The unit cell of claim 15, wherein the unit cell is a first unit cell of a reconfigurable intelligent surface comprising the first unit cell and a second unit cell, and wherein the individually controllable heating elements of the first unit cell are controlled to change the operational rotational angle of the phase change material to the changed rotational angle to create destructive interference of the electromagnetic wave as redirected from the first unit cell with the electromagnetic wave as redirected from the second unit cell.

18. The unit cell of claim 15, wherein the unit cell comprises a thermally conductive layer between the phase change material and the heater network.

19. The unit cell of claim 15, wherein the unit cell comprises a thermal insulator layer and a dielectric layer, and wherein the thermal insulator layer is positioned between the heater network and a dielectric layer of the unit cell.

20. The unit cell of claim 19, wherein the phase change material in the lower resistance state and the dielectric layer forms a capacitor having a capacitance value determined by the operational width of the phase change material in the lower resistance state.
